(19) United States
(12) Patent Application Publication
(10) Pub. No.: US 2026/0179679 A1
(43) Pub. Date: Jun. 25, 2026

(54) STACKED MEMORY CELL STRUCTURE AND METHOD OF FORMING THE SAME

(71) Applicant: Taiwan Semiconductor Manufacturing Company, LTD., Hsinchu (TW)

(72) Inventors: Sheng-Chih Lai, Hsinchu (TW); Ken-Ichi Goto, Hsinchu (TW); Kenichi Sano, Hsinchu (TW)

(21) Appl. No.: 18/999,540

(22) Filed: Dec. 23, 2024

(51) Int. Cl. G11C 11/4096; G11C 5/06

(52) U.S. Cl. CPC G11C 11/4096; G11C 5/063

(57) ABSTRACT

A semiconductor memory cell structure and method of fabricating same structure includes one or more bit cells including a stacked read transistor and write transistor, each bit cell further including read bit line(s), read word line(s), write bit line(s), write word line(s), and a storage node isolated from other bit cell structures. The bit cell(s) further include a read word line to storage node voltage coupler structure which is proximately located near the read word line and storage node, and the voltage coupler is configured as a winged gate or a wraparound read word line.

### BACKGROUND

The following relates to semiconductor integrated circuits (ICs) employing transistor memory cells, such as dynamic random-access memory (DRAM) transistor cells and arrays, and to the manufacturing thereof.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of an integrated circuit (IC) structure (Embodiment 1) including a 3x1 vertically stacked DRAM memory cell array, each memory cell including a read transistor read word line (RWL) to storage node (SN) voltage coupler (VCoupler) having a winged gate proximate to the RWL according to an example embodiment of the present disclosure.

FIG. 1B is a schematic representation of the IC shown in FIG. 1A (Embodiment 1).

FIG. 1C is a simplified top view of the IC shown in FIG. 1A (Embodiment 1) according to an example embodiment of this disclosure.

FIG. 1D is an enlarged detail view of the winged gate RWL to SN Vcoupler shown in FIGS. 1A-1C.

FIG. 1E is a graph of the read transistor drain current (Id) versus the SN voltage (Vsn) according to an example embodiment of this disclosure.

FIG. 2A is a top view of an IC structure including a 3x3 vertically stacked DRAM memory cell array or bank, each memory cell including a read transistor RWL to SN VCoupler having a winged gate proximate to the RWL according to an example embodiment of the present disclosure.

FIG. 2B is a schematical representation of the IC structure including a read operation selecting or asserting a RWL, while other RWLs are not asserted, and the operational states of the memory cells in the bank according to an example embodiment of the present disclosure.

FIGS. 3A-3H illustrates various fabrication stages associated with the fabrication of an IC structure (Embodiment 1) including a 3x1 vertically stacked DRAM memory cell array, each memory cell including a read transistor RWL to SN VCoupler having a winged gate proximate to the RWL according to an example embodiment of the present disclosure.

FIG. 4 is a cross sectional view of an IC structure (Embodiment 2) including a 3x1 vertically stacked DRAM memory cell array, each memory cell including a read transistor RWL to storage node SN VCoupler having a wraparound RWL proximate to the SN according to an example embodiment of the present disclosure.

FIG. 5 illustrates a method of forming an IC including a vertically stacked DRAM memory cell array according to an example embodiment of the present disclosure, each memory cell including a read transistor RWL to SN VCoupler having a winged gate.

FIG. 6 illustrates a method of forming an IC including a vertically stacked DRAM memory cell array according to an example embodiment of the present disclosure, each memory cell including a read transistor RWL to SN Vcoupler having a wraparound RWL.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer,” as used herein, may include a single layers or multiple layers.

The term “conductive feature,” as may be used herein refers to a metallization layer contact, patterned metallization layer contact, or other electrical metal contact.

The term “intermetal dielectric” (IMD) film or layer, as may be used herein, refers to a dielectric/ insulation material(s) layer between two metal layers.

The term “interlayer dielectric” (ILD) layer, as may be used herein, refers to an insulating structure of material(s) placed between two conductive layers.

The term “line” and “metal line,” as may be used herein, is a conductive path that is created during the back end of line (BEOL) process and transmits electrical signals through a semiconductor chip's circuit pattern.

The term “coupler and “voltage coupler”, as may be used herein, refers to a semiconductor structure that provides, i.e., couples, a first/input voltage from a first semiconductor structure feature to a second/output semiconductor feature, and the term “coupler ratio” and “coupling ratio”, as used herein to describe a “coupler” and “voltage coupler”, refers to the ratio of the coupler second/output voltage to the first/input voltage.

The term “stacked” and “vertically stacked” as used herein, refers to the stacking or forming of a two or more transistor structures where a first and second transistor are substantially arranged or formed in an elongated pattern in contrast to a planar structure that includes a side-by- side arrangement of two or more transistor structures. The term “vertical” or “vertically” is not relative to gravity and can include a lateral layout where a first transistor is laterally stacked and formed adjacent to a second lateral transistor with structures as disclosed herein.

In general, some embodiments disclosed herein relate to semiconductor devices, including vertically stacked memory cell structures and methods of forming the same. Specifically, this disclosure provides for the optimization of memory cell IC structures, such as DRAM transistor memory cells, arrays, banks, etc. by providing transistor memory cell structures having vertically stacked non-destructive Read DRAM transistor memory cells with winged gates (Embodiment 1) proximate a storage node (SN) of a memory cell and wraparound read word lines (Embodiment 2) to enhance a sensing window of the memory cell device by using a storage node (SN) coupler structure to coupe a write transistor source/drain to the read word line of a 2 transistor (T), 3T, or 4T. etc. memory cell transistor structure. While this disclosure focuses on a 2T memory cell field effect transistor (FET) structure, it is to be understood that other transistor memory structures are within the scope of this disclosure.

A two-transistor memory cell as disclosed herein is a type of DRAM cell that uses two transistors, i.e., 2T, instead of a capacitor and a transistor. One transistor acts as the write transistor and the other as the read transistor. The DRAM memory cell stores bit data, or bit signals representing two logical state values of a bit, including 0 and 1. Generally, DRAM is volatile memory that loses its data quickly when power is removed. To prevent this, DRAM requires an external memory refresh circuit to periodically rewrite the data in the capacitors. In addition, a sensing circuit is operatively connected to the memory cell bit outputs, when read, to provide signal processing of the stored bit value signals required for computer processing, etc. 2T memory cells have several advantages over larger memory cell structures, including but not limited to, low power, high density, long retention time, etc.

Some conventional 2T, 3T, 4T, etc. memory cell structures suffer from problems or design limitations associated with a relatively large cell-size as a result of the planar side-by-side structure and layout of the memory cell read and write transistors, and relatively large sneak currents or leakage currents are generated by relatively large bit cells electrically connected to a common bit line which can reduce or destroy a desired sensing signal output of the memory cell structure or device, thereby leading to a failure to read and process a bit signal. Specifically, conventional 2T memory cell structures operate with digital memory states (0 and 1) defined by high and low conductance states of the memory cell read transistor, respectively. Consequently, when a read transistor is turned on, i.e., the read word line is selected or asserted, to read an associated SN state, the high conductance state of unselected cells within an array of neighboring and connected bit cells reduces the sensing window of the selected cell because of opposing polarity sneak currents generated by the other unselected cells due to the high conductivity state of the other neighboring read transistors, which are unselected by the read word line, in the memory structure array.

In other words, conventional practices of using a side-by-side write transistor and read transistor and planar type transistor memory cell structure may have a limited or problematic sensing window that is susceptible to sneak current generated noise, the sensing window being the window between state 1 and state 0 for sense amplification to identify an associated bit memory state of 1 or 0.

This disclosure, and the example embodiments described herein, provide a transistor memory cell structure which minimizes or reduces the memory cell size by stacking the read and write transistors of a DRAM memory cell. Furthermore, this disclosure and example embodiments described herein, reduce or minimize sneak/leakage current, according to an example Embodiment 1, by coupling the read word line to the SN of the memory cell, where the structure of an overlapping area of a winged gate(s) of the read transistor over a read word line is proximately located near the winged gate(s) and the overlapping structure is designed to provide a desired coupling ratio of an input read word line voltage, i.e., assertion or selection line, to the SN region of the memory device, thereby reducing noise generated from sneak currents. According to an example Embodiment 2 the sneak/leakage current is reduced or minimized by coupling the read word line to the SN of the memory cell, where the structure of an overlapping area of a read word line that is wrapped around the gate of the read transistor at a distal end opposite the SN distal end of the gate structure, the overlapping or wrapped read word line structure is designed to provide a desired coupling ratio of an input read word line voltage, i.e., assertion or selection line, to the SN region of the memory device, thereby reducing noise generated from sneak currents.

The nondestructive operation of the disclosed memory cell structure or device means that the SN signal is not degraded after a read operation because there is no charge sharing. However, refresh is needed once the SN signal is lost after a data retention time, e.g., > 100 ms, due to the leakage current of the write transistor. The sneak current is the leakage current from an unselected memory cell(s) during a read operation which causes sensing window reduction due to the higher noise induced by the leakage current.

According to an example embodiment, the read transistor RWL to SN coupler generates a 200mV to 500 mV coupling voltage to the SN by a selected or asserted RWL, which is desired for adequate operation of the read transistor according an example memory cell structure. The coupling ratio of the RWL to SN to generate a desired coupling voltage is dependent on (1) the overlaying area between the SN and RWL, and (2) the thicknesses and dielectric constants of a high-k dielectric and conductive channel between the SN and RWL. For example, if a selected RWL voltage is 1V, the coupling ratio should be about 0.2 to 0.5 to create about 200mV to 500mV coupling voltage from a 1 V asserted or RWL to the SN. An additional feature of the disclosed Embodiments, including Embodiments 1 and 2, is the use of an island or isolated metal SN region, in contrast to and distinguishable from other memory cell designs that include a common metal line that electrically connects adjacent or other of memory cell SNs. The isolated metal SN is formed on a gate structure of the read transistor and is electrically isolated from other memory cell SNs. In other words, a common SN metal line is not used.

As will further described below with reference to the figures, the disclosed memory cells include a read transistor, RBL and RWL structure/layout including a RWL to SN voltage coupler structure. In operation, both memory states (0 and 1) of the memory cell, i.e., the SN voltage states, operate to maintain the read transistor in an off state, but at different SN voltage levels corresponding to a memory state 1 and memory state 0. This is accomplished by the use of the disclosed RWL to SN coupler structure that effectively provides a different effective threshold voltages (Vt) levels for the read transistor depending on whether or not the RWL is asserted, i.e., the RWL voltage. In effect, the read transistor with the RWL asserted becomes a read transistor with a relatively low Vt state that can be turned on (i.e., becoming high conductance) by the voltage coupling of selected read word-line (RWL). In contrast, the read transistor with the RWL unasserted becomes a read transistor with a relatively high Vt state that is not turned on (i.e., becoming low conductance) because there is no voltage coupling of unselected read word-line (RWL), e.g., 0 V. Furthermore, because the disclosed RWL to SN coupler structures only operate to provide a coupling voltage to the SN when a RWL is asserted, thereby providing an input voltage to the coupler, the read transistor remains in an off state whether the memory state of the device or structure, i.e., SN voltage, is high or low. In other words, when the read transistor is in an unselected state, the transistor conduction channel is at a low conductance state and the sneak current is minimized or is about zero.

Advantages/benefits of the disclosure, and the example embodiments described herein, include but are not limited to, a greater memory cell density layout because of smaller cell size and vertically stacking of the read and write transistors. In addition, an improvement in performance is obtained with a relatively higher speed of operation and lower power consumption due to the elimination or minimization of sneak current.

The disclosed embodiments provided herein are directed to a DRAM including a 2T0C (2-transistors and 0 capacitors) layout or configuration. However, other DRAM memory cells including separate write and write transistors, such as 3T, 4T, etc. are within the scope of this disclosure as they may benefit from the use of the vertically stacked transistor structure integrating a RWL to SN coupler, as described herein, to minimize or reduce cell size, improve operational speed and minimize or reduce sneak and leakage currents without deviating from the basic structural design details described herein.

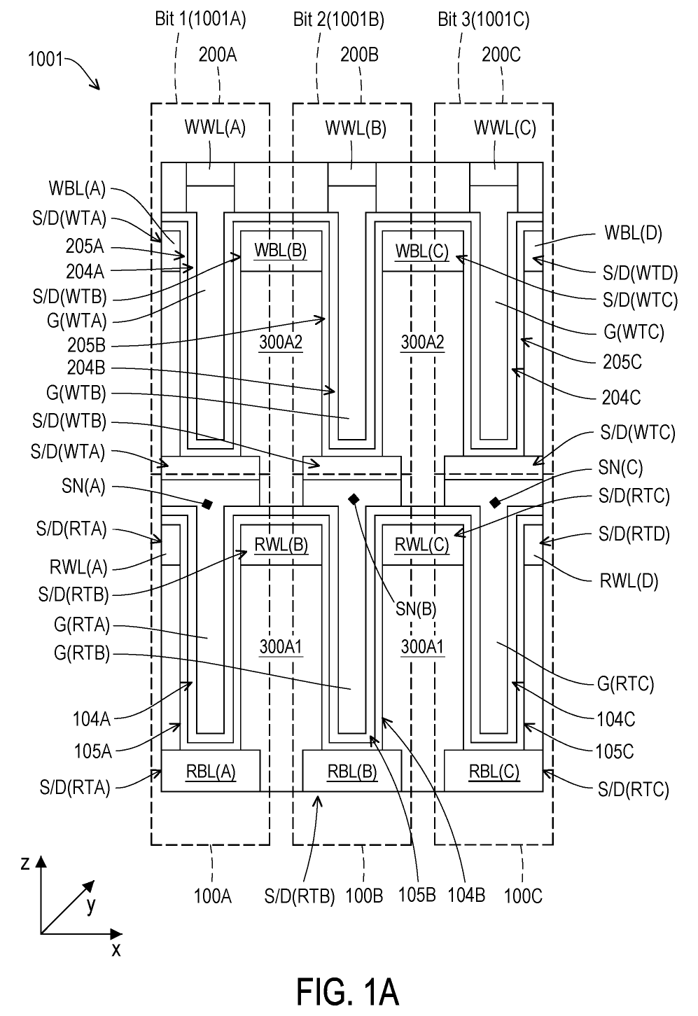

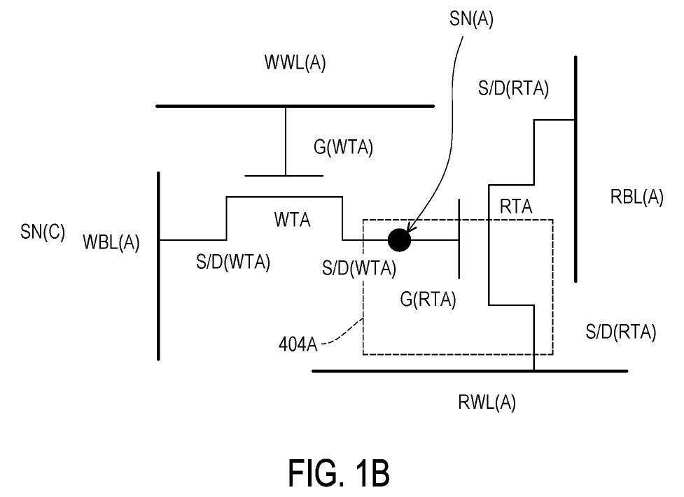

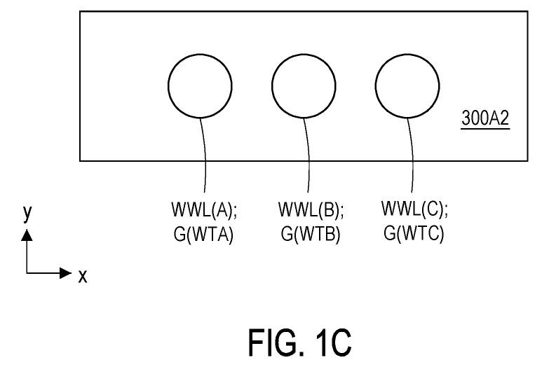

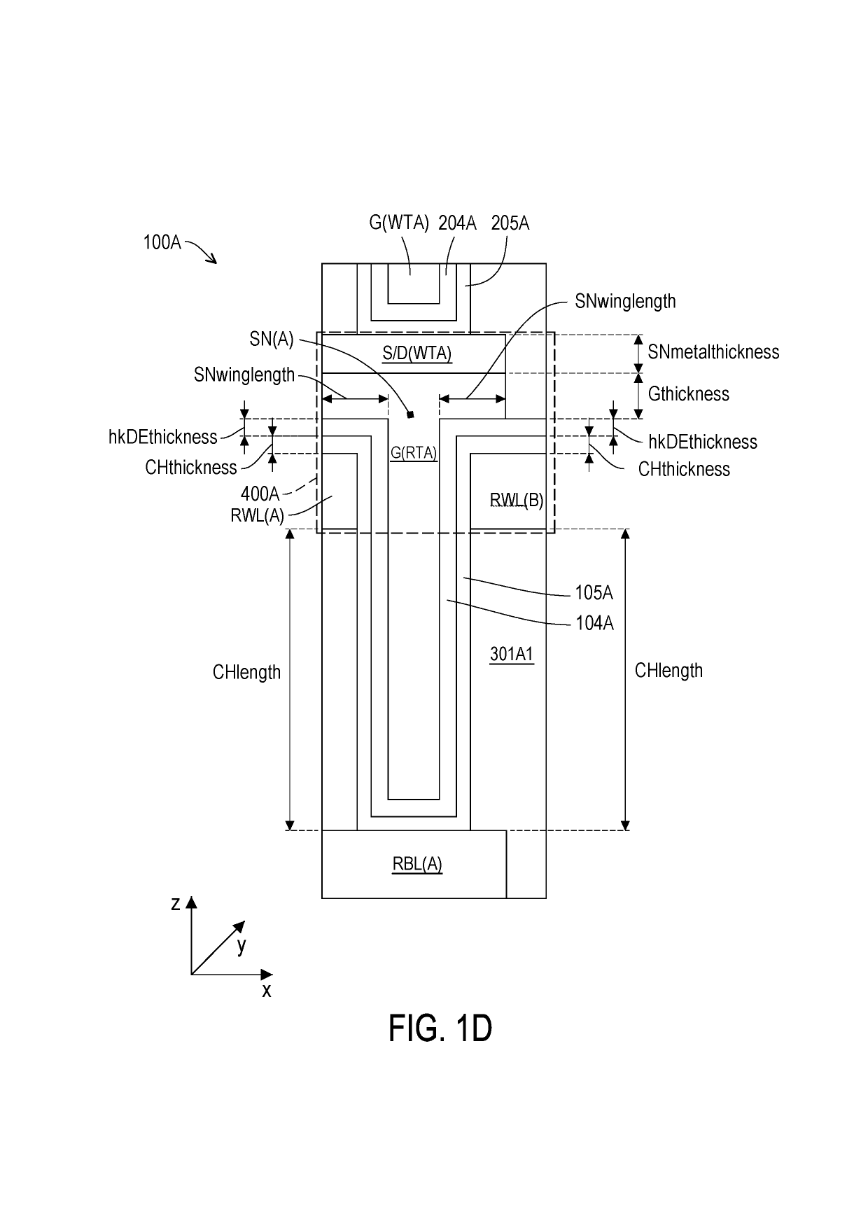

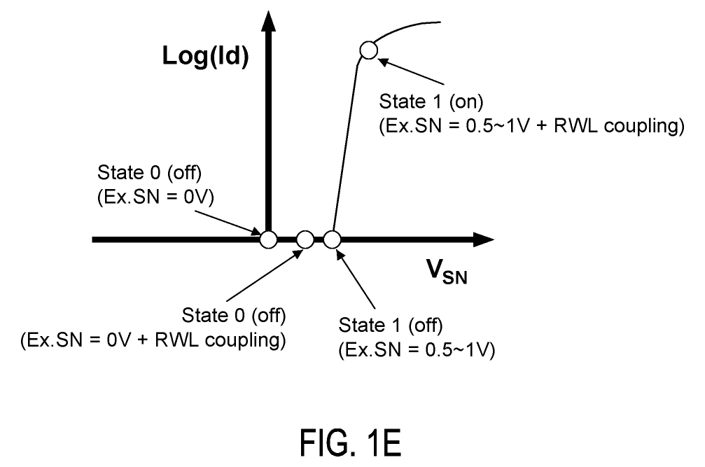

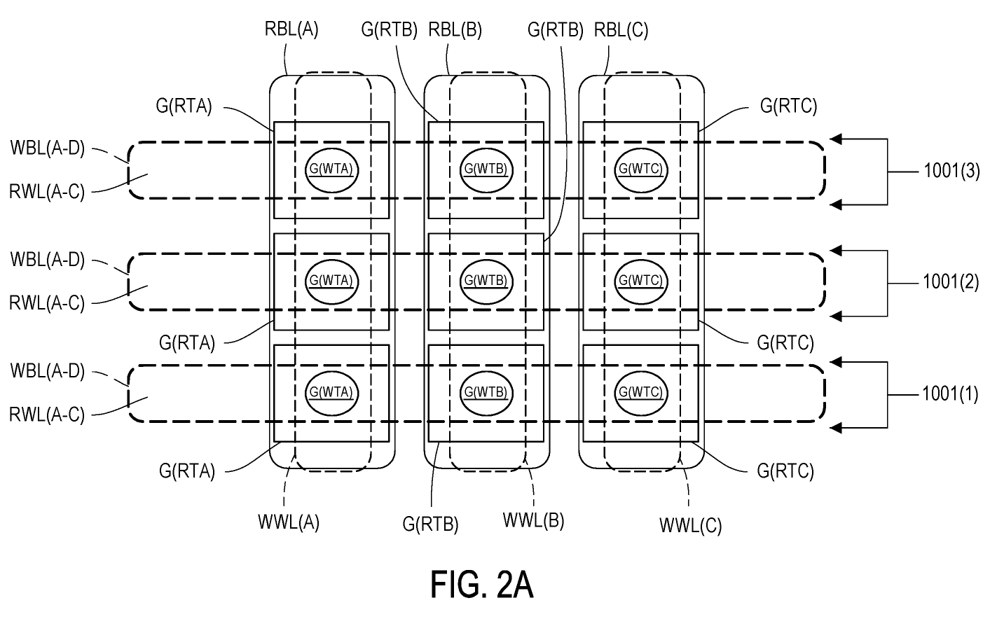

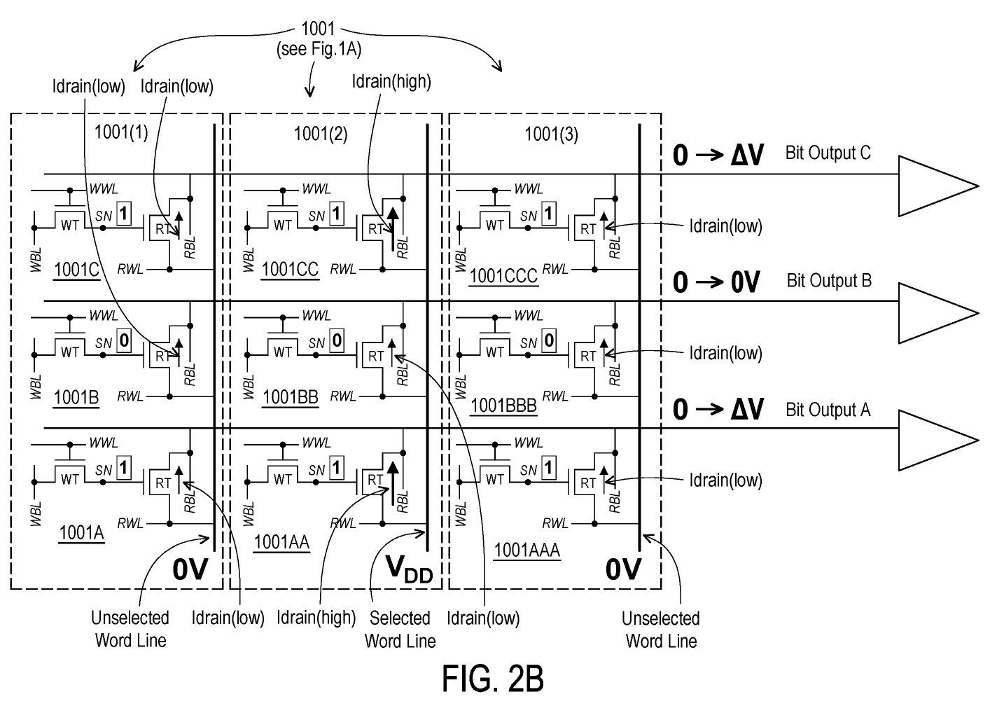

With reference to FIG. 1A, shown is a cross-sectional view of an IC structure (Embodiment 1) including a 3x1 vertically stacked DRAM memory cell array 1001, each memory cell 1001A, 1001B, 1001C including a read transistor read word line (RWL) to storage node (SN) voltage coupler (VCoupler) having a winged gate proximate to the RWL according to an example embodiment of the present disclosure. For further reference, FIG. 1B is a schematic representation of the IC shown in FIG. 1A, FIG. 1C is a simplified top view of the IC shown in FIG. 1A, FIG. 1D is an enlarged detail view of the winged gate RWL to SN Vcoupler shown in FIGS. 1A-1C, and FIG. 1E is a graph of the read transistor drain current (Id) versus the SN voltage (Vsn) according to an example embodiment of this disclosure.

As shown in FIG. 1A, the memory cell array 1001 includes a 3-bit layout, including a 2T bit 1 structure 1001A, a 2T bit 2 structure 1001B, and a 2T bit 3 structure 1001C.

Operationally, within reference to FIG. 1B, each of the 2T, e.g., FET transistor, memory cell bit structures are formed to provide a functional circuit equivalent to that shown in FIG. 1B. Each of the 2T bit cells 1001A, 1001B and 1001C generally operate to provide write, storage and read operations for a single bit, or memory state associated with a logical 1 or 0. While the description that follows focuses on the operation of bit cell 1001A, it is to be understood that the other bit cells 110B and 1001C operate similarly.

During a write operation of the bit cell 1001A, word write line WWL(A) is asserted, which turns ON write transistor by applying a voltage to write transistor gate G(WTA). Consequently, a bit value or representative bit value signal is effectively transferred to the storage node SN(A) at the S/D (source/drain) of the write transistor. The coupling structure of the write transistor S/D(WTA) to the read transistor write line through the read transistor gate G(RTA) and source/drain region (S/D(RTA), to RWL(A), provides the necessary charge retention function of the device to store the written bit signal maintained at storage node SN(A) after the write word line is unasserted.

During a read operation, the read word line RWL(A) is asserted. and read transistor RTA is turned ON, whereby the logical stored voltage value at storage node SN(A) is available to be read or detected at read bit line RBL(A).

According to the example embodiments described herein, that include a RWL to SN voltage coupler structure and isolated SN structure, during a read operation with a SN(A) value of 1, read transistor RTA is in a high conductive channel state, i.e. it is ON, and during a read operation with a SN(A) value of 0, read transistor RTA is in a low conductive channel state, i.e. it is OFF. When the read word line RWL(A) is not asserted or selected, e.g., 0V, the read transistor RTA is in a low conductivity channel state, i.e. is OFF, for the case when the storage node SN(A) is in a low state, i.e. logical bit value 0, and also OFF for a high state condition, i.e. logical bit value 1.

As shown, with further reference to FIG. 1A, the 1x3 bit memory array 1001 includes the following.

A first bit memory cell 1001A including read transistor, e.g., FET transistor, 100A, a stacked write transistor, e.g., FET transistor, 200A, and integrated with the stacked bit cell structure is read bit line RBL(A), read word line RWL(A), write bit line WBL(A) and write word line WWL(A) Read transistor 100B metal gate G(RTA), S/D regions S/D(RTA), and storage node SN(A) provides for the bit cell 1001A receiving and storage of a bit value, as previously described, from write transistor WTA write bit line WBL(A), when write word line WWL(A) is asserted. Metal gate G(WTA) and S/D regions S/D(WTA) provide for the operation of write transistor 200A.

A second bit memory cell 1001B including read transistor, e.g., FET transistor, 100B, a stacked write transistor, e.g., FET transistor, 200B, and integrated with the stacked bit cell structure is read bit line RBL(B), read word line RWL(B), write bit line WBL(B) and write word line WWL(B). Read transistor 100B metal gate G(RTB), S/D regions S/D(RTB) and storage node SN(B) provide for the bit cell 1001B receiving and storage of a bit value, as previously described, from write transistor WTA write bit line WBL(B), when write word line WWL(B) is asserted. Metal gate G(WTB) and S/D regions S/D(WTB) provide for the operation of write transistor 200A.

A third bit memory cell 1001C includes read transistor, e.g., FET transistor, 100C, a stacked write transistor, e.g., FET transistor, 200C, and integrated with the stacked bit cell structure is read bit line RBL(C), read word line RWL(C), write bit line WBL(C) and write word line WWL(C). Read transistor 100C metal gate G(RTC), S/D regions S/D(RTC), and storage node SN(C) provide for the bit cell 1001C receiving and storage of a bit value, as previously described, from write transistor WTC write bit line WBL(C), when write word line WWL(C) is asserted. Metal gate G(WTC) and S/D regions S/D(WTC) provide for the operation of write transistor 200A.

Various details of the Embodiment 1 shown in FIG. 1A are as follows.

According to an example embodiment, write bit lines WBL(A), WBL(B), WBL(C) and WBL(D) region D are all part of a common metal line, and read word lines RWL(A), RWL(B), RWL(C) and RWL(D) are part of another common metal line.

According an example embodiment, conductive channel layers 105A, 105B, 105C, 205A, 205Band 205Care made of indium gallium zinc oxide (IGZO) and/or indium gallium zinc tin oxide IGZTO; high-k dielectric layers 104A, 104B, 104C, 204A, 204B,and 204C are mode of Hafnium oxide (HfO₂), zirconium dioxide ZrO₂) an/or aluminum oxide (Al₂O₃); and metal gates G(RTA), G(RTB), G(RTC), G(WTA), G(WTB) and G(WTC) are made of Titanium Nitride (TiN) and/or Ruthenium (Ru). IMD regions/layers 300A1 and 300A2 materials are Chemical Vapor Deposited Silicon dioxide (CVD SiO₂) or other low-k materials.

According the example embodiment described, the DRAM cells are n-channel MOSFETS, however other types of FET transistors are within the scope of this disclosure, including, but not limited to, p-channel MOSFETS.

According to an example embodiment, the IC 1001 is formed on a wafer made of a semiconducting material, where the IC 1001 is built or formed thereon by conventional semiconductor fabrication techniques, including but not limited to photolithographic techniques such as applying a pattern / structure in a given layer by applying a photoresist layer, patterning the photoresist layer, developing the photoresist layer, and then etching, followed by planarizing and cleaning. While the specific semiconductor fabrication processes required to form the IC 1001 shown are not the focus of this disclosure, for completeness a general description of the semiconductor fabrication processes follows.

The semiconductor substrate materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90°C to about 110°C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

Dielectric structures can be made from any suitable combination of dielectric materials. Examples of dielectric materials may include silicon dioxide (SiO₂), silicon nitride (Sᵢ₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carbonitride (SiCₓO_{y}Nz), or hexagonal boron nitride (hBN). Other dielectric materials may include tantalum oxide (Ta2O5), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material, discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

With reference to FIG. 1D, shown is a detailed view of the read transistor 100A, specifically showing various dimensional parameters of the RWL(A) to SN(A) interface and coupling structure to provide a voltage coupling and associated voltage coupling ratio.

CHlength dimension represents the conductive channel length; CHwidth dimension represents the conductive channel width; CHthickness dimension represents the conductive channel thickness; SNmetalthickness dimension represents the S/D(WTA) top metal layer thickness; SNwinglength dimension represents the overlap area or wing portion length overlapping the read word line RWL(A) to provide voltage coupling of RWL(A) to SN(A); hkDEthicknesss dimension represents the High K dielectric layer 104A thickness; and Gthickness dimension represents the thickness of the metal gate G(RTA).

The RWL(A) to SN(A) voltage coupler ratio is provided based on CHwidth, CHthickness, SNmetalthickness, SNwinglength, hkDEthicknesss and Gthickness. According to some embodiments, one or more of these dimensional properties of the voltage coupler region 400A are designed to provide a desired voltage coupling of RWL(A) to SN(A) as previously described and further described below.

With reference to FIG. 1E, shown is a graph of the read transistor drain current (Id) versus the SN voltage (Vsn) according to an example embodiment of this disclosure. Specifically, the graph shows the conductance of a bit memory cell state 1 and 0 during a read operation, with and without the memory cell selected or asserted by the read word line RWL. The State 1 or 0 is dependent on the SN voltage level and leads to different channel conductance of the read transistor (RTA, RTA and/or RTC).

There are 4 states or conditions illustrated in FIG. 1E, where during a read word line assertion and selection operation, or unasserted read word line assertion, where:

1) RWL asserted and is about 0.5V to 1V, where State 0 (off) (Ex. SN=0V + RWL t SN coupling voltage) which a low conduction channel state and the read transistor is OFF;

2) RWL is asserted and is about 0.5V to 1V, where “Sate 1 (ON) (Ex. SN is about 0.5V to about 1V, + RWL to SN coupling voltage, ex. about 0.5V to about 1V) which is a high conduction channel state and the READ transistor is ON;

3) RWL is unasserted and is about 0 V, where State 0 (off) (Ex. SN=0V) which a low conduction channel state and the read transistor is OFF; and

4) RWL is unasserted and is about 0.5V to 1V, where “Sate 1 (ON) (Ex. SN is about 0.5V to about 1V) which is a low conduction channel state and the READ transistor is OFF.

Stated another way, the graph of the read transistor drain current (Id) versus the SN voltage (Vsn) shows both of high and low channel conductivity Vt states of the read transistor are defined at Vt > 0 (i.e., enhancement mode). According to an example embodiment, Vt is about 10nA*W/L in a standard transfer Id-Vg curve representative of the read transistor structure. According to this equation, “W” is the width of the conductive channel (not shown) and “L” is the length of the conductive channel CHlength as shown in FIG. 1D. According to an example embodiment, CHlength is about 20 nm to about 200nm. According to some embodiments, the W/L ratio varies and is a function of Power, Performance, Area, and Cost (PPAC) optimization.

According to example embodiments, the Vt of the read transistor when in a low conductivity channel state is from about .2V to .4V, and the Vt of the read transistor when in a high conductivity channel state is from about 0.6V to about 0.8V. In order to adjust the Vt to more positive, there are several techniques that can used in amorphous oxide semiconductor (e.g., IGZO, IGZTO, indium(III) oxide (In₂O₃) , ITO, …). Also, forming a thinner channel thickness. e.g., from about 2nm to about 8nm, forming the conductive channel with less indium concentration to reduce the concentration of electron carriers, e.g., indium at a range of about 5% to about 30% and providing a high work-function metal gate, such as TiN, tungsten (W) or Ru.

With reference to FIG. 2A, shown is a top view of an IC structure including a 3x3 vertically stacked DRAM memory cell array or bank, each memory cell including a read transistor RWL to SN VCoupler having a winged gate proximate to the RWL according to an example embodiment of the present disclosure, and FIG. 2B is a schematical representation of the IC structure including a read operation selecting or asserting a RWL, while other RWLs are not asserted, and the operational states of the memory cells in the bank according to an example embodiment of the present disclosure.

As shown in FIG. 2A, the IC memory cell array includes a 3X 3 memory cell array having stacked memory 1001(1), 1001(2) and 1001(3) as previously described with reference to 1x3 memory cells 1001 and shown in FIGS. 1A-1E.

Visible features of each of the 1x3 memory cell 1001(1), 1001(2) and 1001(3) include write bit lines WBL(A), WBL(B), WBL(C), and WBL(D), write word lines WWL(A), WWL(B), and WWL(C), read word lines RWL(A), RWL(B) and RWL(C) and read word bit lines RBL(A), RBL(B) and RBL(C). Also shown are 1x3 memory cells 1001(1) write transistor gates G(WTA), G(WTB) and G(WTC), and read transistor winged gates G(RTA), G(RTB) and G(RTC). Transistor gates G(WTA), G(WTB) and G(WTC) are shown with rectangular or square winged gate profiles, however other winged gate shape profiles can be used, e.g., circular, polygon shaped, etc.

To provide for the functionality of the 3x3 memory cell array shown in FIG. 2B, in addition to the structural features of each of the 1x3 memory cells 1001(1), 1001(2) and 1001(3) as previously described with reference to FIGS. 1A-1E,), read bit lines (A-C) lines are connected (vertically as shown) for each 1x3 memory cell 1001(1), 1001(2) and 1001(3) for a respective bit column location of the 1x3 memory arrays, and 2) word write lines (A-C) are connected (vertically as shown) for each 1x3 memory cell 1001(1), 1001(2) and 1001(3) for a respective bit column location of the 1x3 memory arrays.

Referring to the operational schematic of FIG. 2B, a read operation of the 3x3 memory cell array or bank is shown, where a first 1x3 bit array 1001(1) includes memory cells 1001A, 1001B and 1001C, as previously described with reference to FIGS. 1A-1E; second 1x3 bit array 1001(2) includes memory cells 1001AA, 1001BB and 1001CC, as previously described with reference to FIGS. 1A-1E; and third 1x3 bit array 1001(3) includes memory cells 1001AAA, 1001BBB and 1001CCC, as previously described with reference to FIGS. 1A-1E. In addition, read word line RWL corresponds to RWL(A-C) of FIG. 2A, and bit outputs A, B and C correspond to read bit line RBL(A-C) of FIG. 2A. VDD voltage represents the voltage applied to the RWL for assertion or selection of a desired read word line. e.g., 1 volt.

With a selected or asserted RWL for 1x3 memory cell array 1001(2), with memory cell arrays 1001(1) and 1001(3) unselected, read transistors of bit cells 1001AA and 1001CC are ON, thereby having a high conductivity channel and generating Idrain(high), where all read transistors of memory bit cells 1001A, 1101B, 1001C, 1001BB, 1001AA, 1001BB and 1001CC are OFF and generate Idrain(low) which is a minimal amount of leakage or sneak current, or substantially zero.

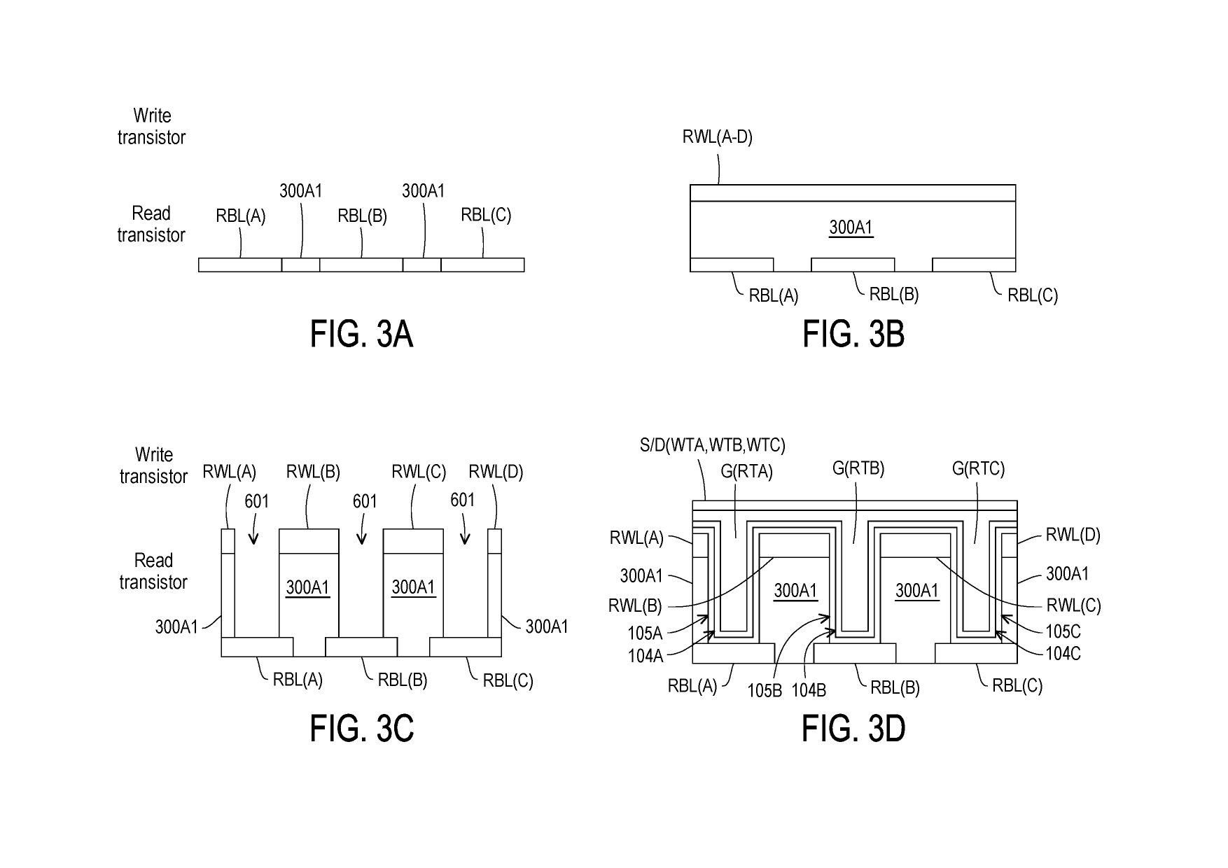

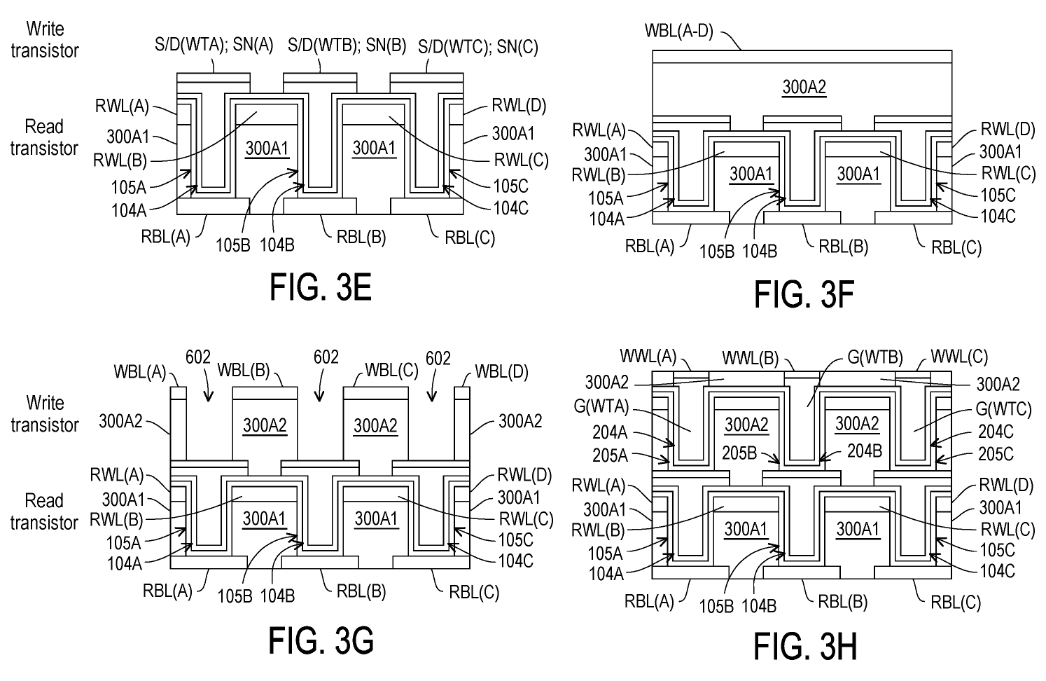

With reference to FIGS. 3A-3H, shown are various fabrication stages associated with the fabrication of an IC structure (Embodiment 1) including a 3x1 vertically stacked DRAM memory cell array, each memory cell including a read transistor RWL to SN VCoupler having a winged gate proximate to the RWL according to an example embodiment of the present disclosure.

FIG. 3A shows an initial stage after previously processing of a semiconductor substrate to provide a read bit line metallization layer. As shown, the RBL metal layer is pattern etched to form RBL(A), RBL(B) and RBL(C) and etch cavities are filled to form intermetal dielectric (IMD) regions 300A1 with an epitaxial growth process.

FIG. 3B shows the next fabrication stage, where IMD region 300A1 is completed and a metallization process is used to form read word line metal layer RWL(A-D).

FIG. 3C shows the next fabrication stage, where channel holes 601 between each of read word lines RWL(A-D) are formed with an etching process. The channel holes 601 extend from read bit lines RBL(A-C) to read word lines RWL(A-D) and provide a channel for subsequent processing to form a gate and conductive layer for each of the read transistors.

FIG. 3D shows the next fabrication stage, where a channel layer 104A-104C, (ex., IGZO, IGZTO) high-k layers 105A-105C, (ex., hafnium(IV) oxide (HfO₂), ZrO₂ or Al₂O₃)), metal gates G(RTA), G(RTB) and G(RTC), (ex. TiN or Ru) and top metal layer S/D(WTA,WTB,WTC). The fabrication stage shown includes a top metal layer S/D(WTA,WTB,WTC) to provide the S/D of subsequently formed write transistors in the following stages of fabrication.

FIG. 3E shows the next fabrication stage, where an etching process is performed to create discrete winged gates for each of gates G(RTA), G(RTB) and G(RTC), and discrete metal storage nodes SN(A), SN(B) and SN(C), where the storage nodes are each electrically isolated from each other and only electrically connected to their respective metal gates.

FIG. 3F shows the next fabrication stage, where IMD region 300A2 is completed and a metallization process is used to form write word line metal layer WWL(A-D).

FIG. 3G shows the next fabrication stage, where channel holes 602 between each of write bit lines RWBL(A-D) are formed with an etching process. The channel holes 602 extending from storage nodes SN(A-D) and providing a channel for subsequent processing to form a gate and conductive layer for each of the write transistors.

FIG. 3H shows the next fabrication stage, where a channel layer 204A-204C, (ex., IGZO, IGZTO) high-k layers 205A-205C, (ex., hafnium(IV) oxide (HfO₂), ZrO₂ or Al₂O₃)), metal gates G(WTA), G(WTB) and G(WTC), (ex. TiN or Ru) and write word line metal layers WWL(A-C) are formed to provide the stacked transistor memory cell 1001 with a winged gate and isolated storage node configuration as shown in FIG. 1A.

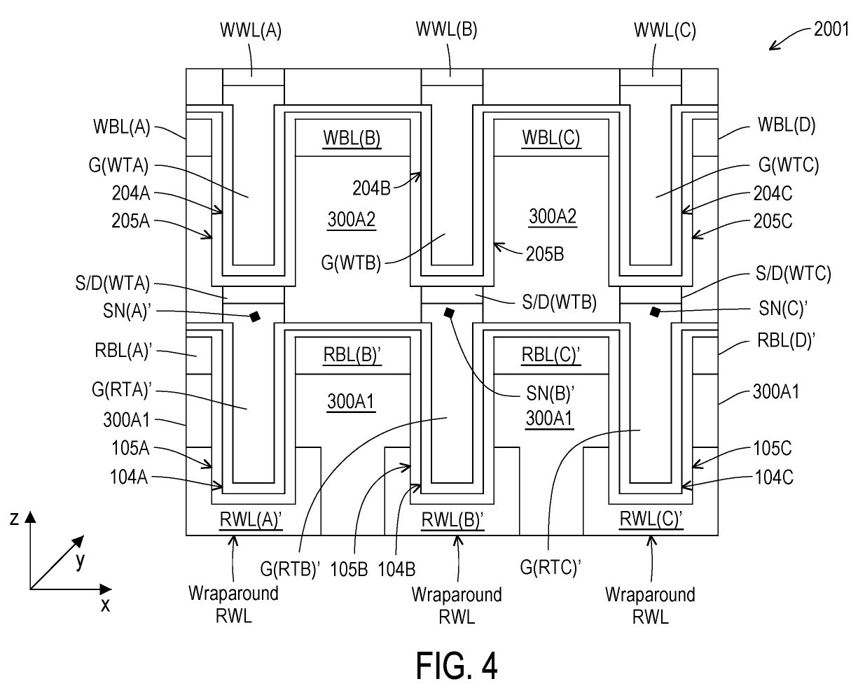

With reference to FIG. 4, shown is a cross sectional view of another IC structure 2001 (Embodiment 2) including a 3x1 vertically stacked DRAM memory cell array, each memory cell including a read transistor RWL to storage node SN VCoupler having a wraparound RWL proximate to the SN according to an example embodiment of the present disclosure.

In contrast to the winged gate structure of Embodiment 11001, wraparound read word lines RWL (A)’, (RWL(B)’ and RWL(C)’ wraparound or cap a first distal end of the read transistor gate structures G(RTA), G(RTB)’ and G(RTC), respectively, and the read bit lines RBL(A)’, RBL(B)’ and RBL(C)’ are formed proximate to a second distal end of the read transistor gate structures G(RTA), G(RTB)’ and G(RTC), respectively. In other words, the RBL and RWL regions are reversed relative to the location of the RBL and RWL of Embodiment 11001. According to Embodiment 22001, a RWL to storage node SN voltage coupler is formed with the overlap area provided by the wraparound RWL proximate to the SN gate region of the read transistors. Similar to Embodiment 11001, the overlap area physical properties, such as RWL metal recess depth, width, length and material are selected to provide a desired voltage coupling or coupling ratio of the RWL(A)’ to SN(A)’, RWL(B)’ to SN(B)’, and RWL(C)’ to SN(C)’ for operation of the 1x3 memory cell bit array as previously described with reference to FIGS. 1A-1E, and FIG. 2A and 2B. Fabrication steps and stages for Embodiment 22001 are similar to those previously described with reference to FIGS. 3A-3H, with appropriate revision to recess the bottom metal read word lines during the hole etch of the vertical read transistors, thereby providing a coupling ratio between the read word lines and the gate of storage node.

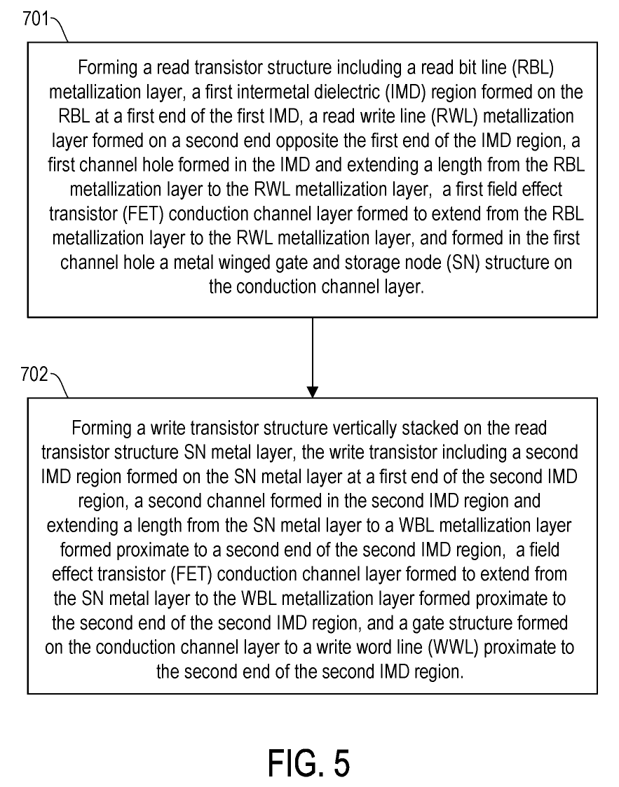

With reference to FIG. 5, shown is a method of forming an IC including a vertically stacked DRAM memory cell array according to an example embodiment of the present disclosure, each memory cell including a read transistor RWL to SN VCoupler having a winged gate.

At step 701, the method forms a read transistor structure including a read bit line (RBL) metallization layer, a first intermetal dielectric (IMD) region formed on the RBL at a first end of the first IMD, a read write line (RWL) metallization layer formed on a second end opposite the first end of the IMD region, a first channel hole formed in the IMD and extending a length from the RBL metallization layer to the RWL metallization layer, a first field effect transistor (FET) conduction channel layer formed to extend from the RBL metallization layer to the RWL metallization layer, and formed in the first channel hole a metal winged gate and storage node (SN) structure on the conduction channel layer.

At step 702, the method forms a write transistor structure vertically stacked on the read transistor structure SN metal layer, the write transistor including a second IMD region formed on the SN metal layer at a first end of the second IMD region, a second channel formed in the second IMD region and extending a length from the SN metal layer to a WBL metallization layer formed proximate to a second end of the second IMD region, a field effect transistor (FET) conduction channel layer formed to extend from the SN metal layer to the WBL metallization layer formed proximate to the second end of the second IMD region, and a gate structure formed on the conduction channel layer to a write word line (WWL) proximate to the second end of the second IMD region.

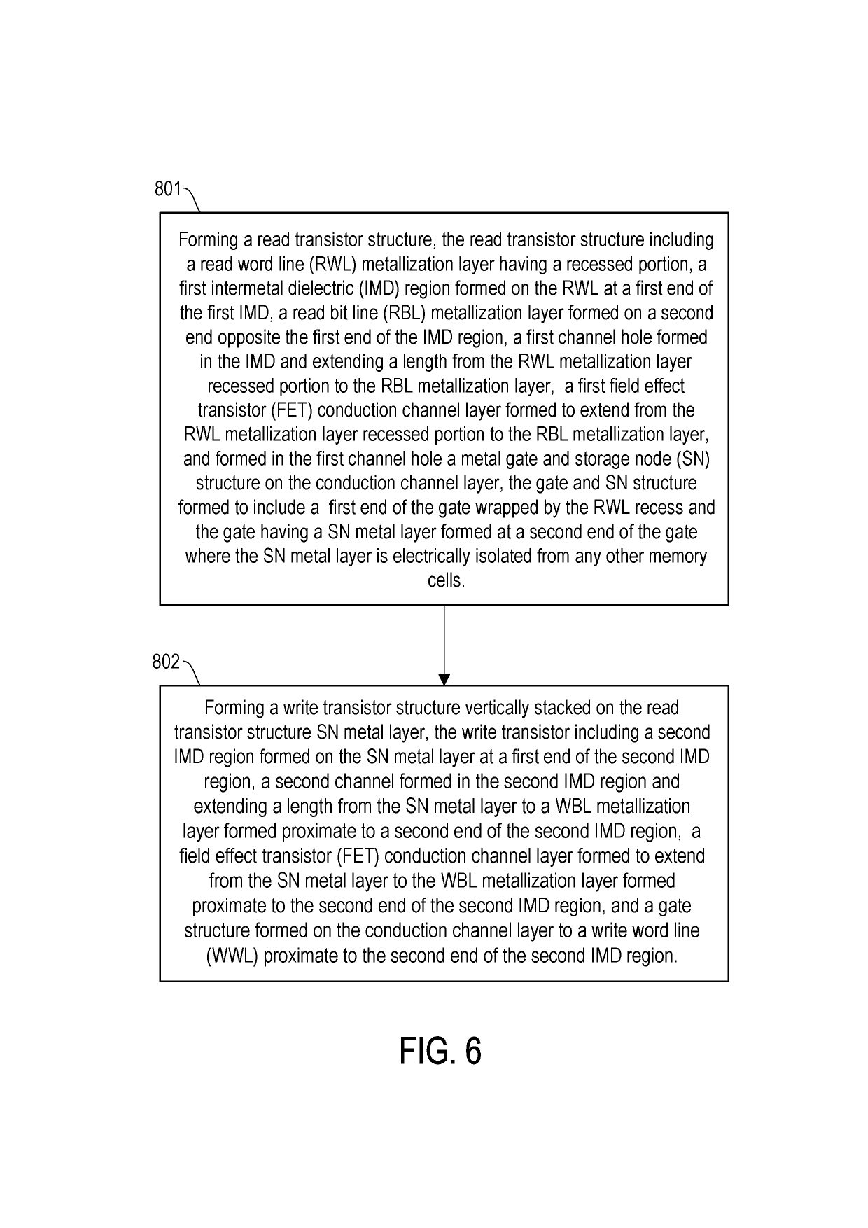

With reference to FIG. 6, shown is a method of forming an IC including a vertically stacked DRAM memory cell array according to an example embodiment of the present disclosure, each memory cell including a read transistor RWL to SN Vcoupler having a wraparound RWL.

At step 801. the method forms a read transistor structure, the read transistor structure including a read word line (RWL) metallization layer having a recessed portion, a first intermetal dielectric (IMD) region formed on the RWL at a first end of the first IMD, a read bit line (RBL) metallization layer formed on a second end opposite the first end of the IMD region, a first channel hole formed in the IMD and extending a length from the RWL metallization layer recessed portion to the RBL metallization layer, a first field effect transistor (FET) conduction channel layer formed to extend from the RWL metallization layer recessed portion to the RBL metallization layer, and formed in the first channel hole a metal gate and storage node (SN) structure on the conduction channel layer, the gate and SN structure formed to include a first end of the gate wrapped by the RWL recess and the gate having a SN metal layer formed at a second end of the gate where the SN metal layer is electrically isolated from any other memory cells.

At step 802, the method forms a write transistor structure vertically stacked on the read transistor structure SN metal layer, the write transistor including a second IMD region formed on the SN metal layer at a first end of the second IMD region, a second channel formed in the second IMD region and extending a length from the SN metal layer to a WBL metallization layer formed proximate to a second end of the second IMD region, a field effect transistor (FET) conduction channel layer formed to extend from the SN metal layer to the WBL metallization layer formed proximate to the second end of the second IMD region, and a gate structure formed on the conduction channel layer to a write word line (WWL) proximate to the second end of the second IMD region.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed IC structures, devices, and methods of forming the same, provide transistor memory bit cells that include a RWL to SN voltage coupler structure which in turn may improve a sensing window associated with a memory array, for example a DRAM.

In the following, some further embodiments are described.

In a nonlimiting illustrative embodiment, a method of forming a stacked transistor memory cell comprising: forming in a substrate a read transistor structure, the read transistor structure including a read bit line (RBL) metallization layer formed on the substrate, a first intermetal dielectric (IMD) region formed on the RBL at a first end of the first IMD, a read write line (RWL) metallization layer formed on a second end opposite the first end of the IMD region, a first channel hole formed in the IMD and extending a length from the RBL metallization layer to the RWL metallization layer, a first field effect transistor (FET) conduction channel layer formed to extend from the RBL metallization layer to the RWL metallization layer, and formed in the first channel hole a metal winged gate and storage node (SN) structure on the first FET conduction channel layer, the winged gate and SN structure formed to include a wing portion proximate a RWL end of the first FET conduction channel layer and substantially orthogonal to the length of the channel, and the winged gate having a SN metal layer formed thereon which is electrically isolated from any other memory cells; and forming a write transistor structure vertically stacked on the read transistor structure SN metal layer, the write transistor including a second IMD region formed on the SN metal layer at a first end of the second IMD region, a second channel formed in the second IMD region and extending a length from the SN metal layer to a WBL metallization layer formed proximate to a second end of the second IMD region, a second field effect transistor (FET) conduction channel layer formed to extend from the SN metal layer to the WBL metallization layer formed proximate to the second end of the second IMD region, and a gate structure formed on the second FET conduction channel layer to a write word line (WWL) proximate to the second end of the second IMD region.

In another nonlimiting illustrative embodiment, a vertically stacked transistor device comprising: a read transistor structure including: a read bit line (RBL) metallization layer formed on a substrate; a first intermetal dielectric (IMD) region formed on the RBL at a first end of the first IMD; a read write line (RWL) metallization layer formed on a second end opposite the first end of the IMD region; a first channel hole formed in the IMD and extending a length from the RBL metallization layer to the RWL metallization layer; a first field effect transistor (FET) conduction channel layer extending from the RBL metallization layer to the RWL metallization layer; and a metal winged gate and storage node (SN) structure formed on the first FET conduction channel layer, the winged gate and SN structure including a wing portion proximate a RWL end of the conduction channel layer and substantially orthogonal to the length of the channel, and the winged gate having a SN metal layer formed thereon which is electrically isolated from any other memory cells; and a write transistor structure vertically stacked on the read transistor structure SN metal layer, the write transistor including: a second IMD region formed on the SN metal layer at a first end of the second IMD region; a second channel formed in the second IMD region and extending a length from the SN metal layer to a WBL metallization layer formed proximate to a second end of the second IMD region; and a second field effect transistor (FET) conduction channel layer formed to extend from the SN metal layer to the WBL metallization layer formed proximate to the second end of the second IMD region, and a gate structure formed on the second conduction channel layer to a write word line (WWL) proximate to the second end of the second IMD region.

In another nonlimiting illustrative embodiment, a method of forming a stacked transistor memory cell comprising: forming in a substrate a read transistor structure, the read transistor structure including a read word line (RWL) metallization layer having a recessed portion formed on the substrate, a first intermetal dielectric (IMD) region formed on the RWL at a first end of the first IMD, a read bit line (RBL) metallization layer formed on a second end opposite the first end of the IMD region, a first channel hole formed in the IMD and extending a length from the RWL metallization layer recessed portion to the RBL metallization layer, a first field effect transistor (FET) conduction channel layer formed to extend from the RWL metallization layer recessed portion to the RBL metallization layer, and formed in the first channel hole a metal gate and storage node (SN) structure on the conduction channel layer, the gate and SN structure formed to include a first end of the gate wrapped by the RWL recess and the gate having a SN metal layer formed at a second end of the gate where the SN metal layer is electrically isolated from any other memory cells; and forming a write transistor structure vertically stacked on the read transistor structure SN metal layer, the write transistor including a second IMD region formed on the SN metal layer at a first end of the second IMD region, a second channel formed in the second IMD region and extending a length from the SN metal layer to a WBL metallization layer formed proximate to a second end of the second IMD region, a second field effect transistor (FET) conduction channel layer formed to extend from the SN metal layer to the WBL metallization layer formed proximate to the second end of the second IMD region, and a gate structure formed on the second FET conduction channel layer to a write word line (WWL) proximate to the second end of the second IMD region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a stacked transistor memory cell comprising:
forming in a substrate a read transistor structure, the read transistor structure including a read bit line (RBL) metallization layer formed on the substrate, a first intermetal dielectric (IMD) region formed on the RBL at a first end of the first IMD, a read write line (RWL) metallization layer formed on a second end opposite the first end of the IMD region, a first channel hole formed in the IMD and extending a length from the RBL metallization layer to the RWL metallization layer, a first field effect transistor (FET) conduction channel layer formed to extend from the RBL metallization layer to the RWL metallization layer, and formed in the first channel hole a metal winged gate and storage node (SN) structure on the conduction channel layer, the winged gate and SN structure formed to include a wing portion proximate a RWL end of the conduction channel layer and substantially orthogonal to the length of the channel, and the winged gate having a SN metal layer formed thereon which is electrically isolated from any other memory cells; and
forming a write transistor structure vertically stacked on the read transistor structure SN metal layer, the write transistor including a second IMD region formed on the SN metal layer at a first end of the second IMD region, a second channel formed in the second IMD region and extending a length from the SN metal layer to a WBL metallization layer formed proximate to a second end of the second IMD region, a second field effect transistor (FET) conduction channel layer formed to extend from the SN metal layer to the WBL metallization layer formed proximate to the second end of the second IMD region, and a gate structure formed on the second field effect transistor (FET) conduction channel layer to a write word line (WWL) proximate to the second end of the second IMD region.

2. The method of claim 1, further comprising:
forming a high-k dielectric layer between the winged gate and the first FET conduction channel layer.

3. The method of claim 2, wherein the metal winged gate is TiN or Ru, the storage node (SN) structure is metal, the first FET conduction channel layer is IGZO or IGZTO, and the high-k dielectric layer is HfO₂ ZrO₂ or Al₂O₃.

4. The method of claim 1, wherein the RWL, winged gate and SN structure is formed to provide a voltage coupler, and associated voltage coupler ratio, from the RWL metallization layer to the SN structure.

5. The method of claim 1, further comprising:
forming the voltage coupler to provide a voltage coupler ratio determined by an overlap area of the winged gate wing portion and RWL layer.

6. The method of claim 1, further comprising:
forming a plurality of adjacent stacked transistor memory cells on a single substrate.

7. The method of claim 1, further comprising:
forming the first FET conduction channel layer to follow the winged portion of the winged gate.

8. The method of claim 1, wherein the read transistor and write transistor are MOSFET transistors and the memory cell is a DRAM.

9. A vertically stacked transistor device comprising:
a read transistor structure including:
a read bit line (RBL) metallization layer formed on a substrate;
a first intermetal dielectric (IMD) region formed on the RBL at a first end
of the first IMD;
a read write line (RWL) metallization layer formed on a second end opposite the first end of the IMD region;
a first channel hole formed in the IMD and extending a length from the RBL metallization layer to the RWL metallization layer;
a first field effect transistor (FET) conduction channel layer extending from the RBL metallization layer to the RWL metallization layer; and
a metal winged gate and storage node (SN) structure formed on the first FET conduction channel layer, the winged gate and SN structure including a wing portion proximate a RWL end of the first FET conduction channel layer and substantially orthogonal to the length of the first FET conduction channel layer, and the winged gate having a SN metal layer formed thereon which is electrically isolated from any other memory cells; and
a write transistor structure vertically stacked on the read transistor structure SN
metal layer, the write transistor including:
a second IMD region formed on the SN metal layer at a first end of the second
IMD region;
a second channel formed in the second IMD region and extending a length from
the SN metal layer to a WBL metallization layer formed proximate to a second end of the second IMD region; and
a second field effect transistor (FET) conduction channel layer formed to extend
from the SN metal layer to the WBL metallization layer formed proximate to the second end of the second IMD region, and a gate structure formed on the second FET conduction channel layer to a write word line (WWL) proximate to the second end of the second IMD region.

10. The device of claim 9, further comprising:
a high-k dielectric layer formed between the winged gate and the first FET conduction channel layer.

11. The device of claim 10, wherein the metal winged gate is TiN or Ru, the storage node (SN) structure is metal, the first FET conduction channel layer is IGZO or IGZTO, and the high-k dielectric layer is HfO2, ZrO2 or Al2O3.

12. The device of claim 9, wherein the RWL, winged gate and SN structure is formed to provide a voltage coupler, and associated voltage coupler ratio, from the RWL metallization layer to the SN structure.

13. The device of claim 9, further comprising:
a voltage coupler to provide a voltage coupler ratio determined by an overlap area of the winged gate wing portion and RWL layer.

14. The device of claim 9, further comprising:
a plurality of adjacent vertically stacked transistor devices on a single substrate.

15. The device of claim 9, wherein the conduction channel layer follows the winged portion of the winged gate.

16. The device of claim 9, wherein the read transistor and write transistor are MOSFET transistors and the vertically stacked transistor device is a DRAM.

17. A method of forming a stacked transistor memory cell comprising:
forming in a substrate a read transistor structure, the read transistor structure including a read word line (RWL) metallization layer having a recessed portion formed on the substrate, a first intermetal dielectric (IMD) region formed on the RWL at a first end of the first IMD, a read bit line (RBL) metallization layer formed on a second end opposite the first end of the IMD region, a first channel hole formed in the IMD and extending a length from the RWL metallization layer recessed portion to the RBL metallization layer, a first field effect transistor (FET) conduction channel layer formed to extend from the RWL metallization layer recessed portion to the RBL metallization layer, and formed in the first channel hole a metal gate and storage node (SN) structure on the conduction channel layer, the gate and SN structure formed to include a first end of the gate wrapped by the RWL recess and the gate having a SN metal layer formed at a second end of the gate where the SN metal layer is electrically isolated from any other memory cells; and
forming a write transistor structure vertically stacked on the read transistor structure SN metal layer, the write transistor including a second IMD region formed on the SN metal layer at a first end of the second IMD region, a second channel formed in the second IMD region and extending a length from the SN metal layer to a WBL metallization layer formed proximate to a second end of the second IMD region, a second field effect transistor (FET) conduction channel layer formed to extend from the SN metal layer to the WBL metallization layer formed proximate to the second end of the second IMD region, and a gate structure formed on the second FET conduction channel layer to a write word line (WWL) proximate to the second end of the second IMD region.

18. The method of claim 17, wherein an overlap area of the first end of the gate wrapped by the RWL recess is formed to provide a voltage coupler, and associated voltage coupler ratio, from the RWL metallization layer to the SN structure.

19. The method of claim 17, forming a plurality of adjacent stacked transistor memory cells on a single substrate.

20. The method of claim 17, wherein the read transistor and write transistor are MOSFET transistors and the memory cell is a DRAM.
